(19) United States
(12) Patent Application Publication
(10) Pub. No.: US 2023/0353162 A1
(43) Pub. Date: Nov. 2, 2023

(54) SEMICONDUCTOR DEVICE AND FAILURE DETECTION METHOD

(71) Applicant: LAPIS Technology Co., Ltd., Yokohama (JP)

(72) Inventor: Motoki UEDA, Yokohama (JP)

(73) Assignee: LAPIS Technology Co., Ltd., Yokohama (JP)

(21) Appl. No.: 18/187,672

(22) Filed: Mar. 22, 2023

(30) Foreign Application Priority Data
Mar. 31, 2022 (JP) 2022-057972

(51) Int. Cl. H03M 1/10

(52) U.S. Cl. CPC H03M 1/1071

(57) ABSTRACT

A semiconductor device capable of detecting a failure of an A/D converter during execution of a normal A/D conversion operation while suppressing an increase in a circuit size is provided. The semiconductor device includes an addition circuit that receives an input of a first analog voltage signal and adds an offset voltage to the first analog voltage signal to generate a second analog voltage signal, an AD conversion circuit that performs AD conversion of the second analog voltage signal to generate a digital voltage signal, and a determination circuit that determines whether a failure has occurred in the AD conversion circuit based on the digital voltage signal.

### CROSS-REFERENCE TO RELATED APPLICATION

This application claims priority under 35 USC 119 from Japanese Patent Application No. 2022-057972 filed on Mar. 31, 2022, the disclosure of which is incorporated by reference herein.

### BACKGROUND

### Technical Field

The disclosure relates to a semiconductor device, and more particularly to a semiconductor device that constitutes a detection circuit for detecting a failure of an A/D conversion circuit.

### Description of Related Art

In recent years, automobiles have come to be equipped with in-vehicle systems for realizing various functions. A high degree of reliability is required for in-vehicle systems because failures in automobiles affect human lives.

Such in-vehicle systems are equipped with a large number of analog output sensors, and output values of the in-vehicle systems are used for system control. For example, in an airbag, an analog output sensor converts acceleration, pressure, and the like into analog signals and inputs them to a micro controller unit (MCU). The MCU periodically performs A/D conversion of the analog signals input thereto, and determines whether a collision accident has occurred according to a result of the A/D conversion.

An analog voltage output from the analog output sensor is generally used by being converted into digital data by an A/D converter mounted on the MCU. Thus, a failure of the A/D converter is likely to cause a fatal error in the system, and thus it is required to reliably detect a failure of the A/D converter.

Consequently, a semiconductor integrated circuit equipped with a function of detecting failures of A/D converters and D/A converters has been proposed (for example, Patent Document 1 (Japanese Patent Laid-Open No. 2009-71459)).

In the above-described failure detection of the related art, an analog multiplexer that selectively outputs either an input from a sensor or the like or an input from a converted analog voltage of a D/A converter to an A/D converter is provided. When a failure is diagnosed, the analog voltage converted by the D/A converter is input to the A/D converter to perform A/D conversion. Thus, there is a problem that failure detection cannot be performed when the A/D converter is performing a normal A/D conversion operation.

In a case where failure detection is desired to be performed while performing a normal A/D conversion operation of the A/D converter, a separate A/D converter for failure diagnosis is required. For this reason, there is a problem that a circuit size increases.

The disclosure provides a semiconductor device capable of detecting a failure of an A/D converter during execution of a normal A/D conversion operation while suppressing increase in a circuit size.

### SUMMARY

A semiconductor device according to the disclosure includes an addition circuit that receives an input of a first analog voltage signal and adds an offset voltage to the first analog voltage signal to generate a second analog voltage signal, an AD conversion circuit that performs AD conversion of the second analog voltage signal to generate a digital voltage signal, and a determination circuit that determines whether a failure has occurred in the AD conversion circuit based on the digital voltage signal.

A semiconductor device according to the disclosure includes a division circuit that receives an input of a first analog voltage signal and divides the first analog voltage signal by a predetermined value to generate a second analog voltage signal, an AD conversion circuit that performs AD conversion of the second analog voltage signal to generate a digital voltage signal, and a determination circuit that determines whether a failure has occurred in the AD conversion circuit based on the digital voltage signal.

A semiconductor device according to the disclosure includes a subtraction circuit that receives an input of a first analog voltage signal and subtracts an offset voltage from the first analog voltage signal to generate a second analog voltage signal, an AD conversion circuit that performs AD conversion of the second analog voltage signal to generate a digital voltage signal, and a determination circuit that determines whether a failure has occurred in the AD conversion circuit based on the digital voltage signal.

A semiconductor device according to the disclosure includes an addition circuit that receives an input of a first analog voltage signal and adds an offset voltage to the first analog voltage signal to generate a second analog voltage signal, a division circuit that receives an input of the second analog voltage signal and divides the second analog voltage signal by a predetermined value to generate a third analog voltage signal, an AD conversion circuit that performs AD conversion of the third analog voltage signal to generate a digital voltage signal, and a determination circuit that determines whether a failure has occurred in the AD conversion circuit based on the digital voltage signal.

A failure detection method according to the disclosure is a failure detection method of an AD conversion circuit which is executed by a semiconductor device including the AD conversion circuit, the failure detection method including receiving an input of a first analog voltage signal and adding an offset voltage to the first analog voltage signal to generate a second analog voltage signal, causing the AD conversion circuit to perform AD conversion of the second analog voltage signal to generate a digital voltage signal corresponding to the second analog voltage signal, and determining whether a failure has occurred in the AD conversion circuit based on the digital voltage signal.

A failure detection method according to the disclosure is a failure detection method of an AD conversion circuit executed by a semiconductor device including the AD conversion circuit, the failure detection method including receiving an input of a first analog voltage signal and dividing the first analog voltage signal by a predetermined value to generate a second analog voltage signal, causing the AD conversion circuit to perform AD conversion of the second analog voltage signal to generate a digital voltage signal corresponding to the second analog voltage signal, and determining whether a failure has occurred in the AD conversion circuit based on the digital voltage signal.

A failure detection method according to the disclosure is a failure detection method of an AD conversion circuit executed by a semiconductor device including the AD conversion circuit, the failure detection method including receiving an input of a first analog voltage signal and subtracting an offset voltage from the first analog voltage signal to generate a second analog voltage signal, causing the AD conversion circuit to perform AD conversion of the second analog voltage signal to generate a digital voltage signal corresponding to the second analog voltage signal, and determining whether a failure has occurred in the AD conversion circuit based on the digital voltage signal.

Further, a failure detection method according to the disclosure is a failure detection method of an AD conversion circuit executed by a semiconductor device including the AD conversion circuit, the failure detection method including receiving an input of a first analog voltage signal and adding an offset voltage to the first analog voltage signal to generate a second analog voltage signal, receiving an input of the second analog voltage signal and dividing the second analog voltage signal by a predetermined value to generate a third analog voltage signal, causing the AD conversion circuit to perform AD conversion of the third analog voltage signal to generate a digital voltage signal corresponding to the third analog voltage signal, and determining whether a failure has occurred in the AD conversion circuit based on the digital voltage signal.

### BRIEF DESCRIPTION OF THE DRAWINGS

FIG. 1 is a block diagram illustrating a configuration of a semiconductor device of Example 1.

FIG. 2 is a diagram illustrating an example of a configuration of an analog addition circuit.

FIG. 3 is a diagram illustrating another example of the configuration of the analog addition circuit.

FIG. 4 is a block diagram illustrating a configuration of a semiconductor device according to Example 2.

FIG. 5 is a diagram illustrating an example of a configuration of an analog division circuit.

FIG. 6 is a block diagram illustrating a configuration of a semiconductor device according to Example 3.

FIG. 7 is a diagram illustrating an example of a configuration of an analog subtraction circuit.

FIG. 8 is a block diagram illustrating a configuration of a semiconductor device according to a modification example obtained by combining Example 1 and Example 2.

### DESCRIPTION OF THE EMBODIMENTS

Hereinafter, examples of the disclosure will be described with reference to the drawings. In the following description of the examples and the accompanying drawings, substantially the same or equivalent parts are denoted by the same reference numerals and signs.

### Example 1

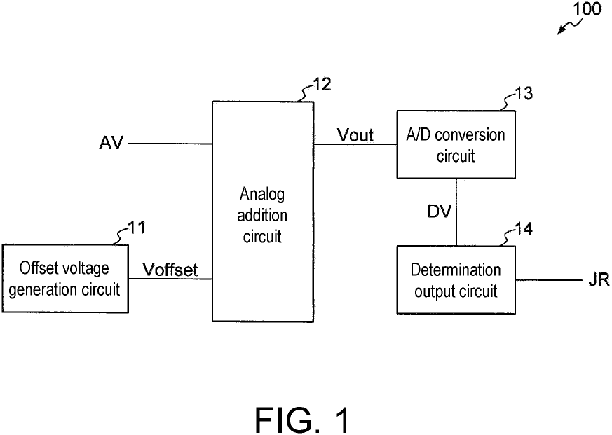

FIG. 1 is a block diagram illustrating a configuration of a semiconductor device 100 according to Example 1 of the disclosure. The semiconductor device 100 is used in a converter for performing analog-digital (A/D) conversion of an output signal of an analog output sensor in an in-vehicle system mounted on a vehicle such as an automobile.

The semiconductor device 100 includes an offset voltage generation circuit 11, an analog addition circuit 12, an A/D conversion circuit 13, and a determination output circuit 14, and is configured as a failure detection circuit for detecting a failure of the A/D conversion circuit 13. An analog input voltage AV, which is a voltage to be subjected to analog-digital (A/D) conversion by the A/D conversion circuit 13, is supplied to the semiconductor device 100 from the outside. For example, in the example of the in-vehicle system described above, an output signal of the analog output sensor is an input voltage AV in this example.

The offset voltage generation circuit 11 is a circuit that generates an offset voltage Voffset, which is an analog voltage to be added to the input voltage AV. The offset voltage generation circuit 11 generates an offset voltage Voffset, for example, based on a power supply voltage (not illustrated) supplied as an operating voltage from the outside of the semiconductor device 100.

The analog addition circuit 12 is a circuit that performs addition processing on the input voltage AV using the offset voltage Voffset. The addition processing in the present example includes not only simple addition of simply adding the input voltage AV and the offset voltage Voffset, but also a case where addition is performed by performing predetermined weighting on the voltages. The analog addition circuit 12 includes a first input terminal that receives an input of the offset voltage Voffset and a second input terminal that receives an input of the input voltage AV.

The analog addition circuit 12 outputs an addition result as an output voltage Vout. That is, in the present example, the output voltage Vout is a second analog voltage signal obtained by adding the offset voltage Voffset to the input voltage AV, which is the first analog voltage signal.

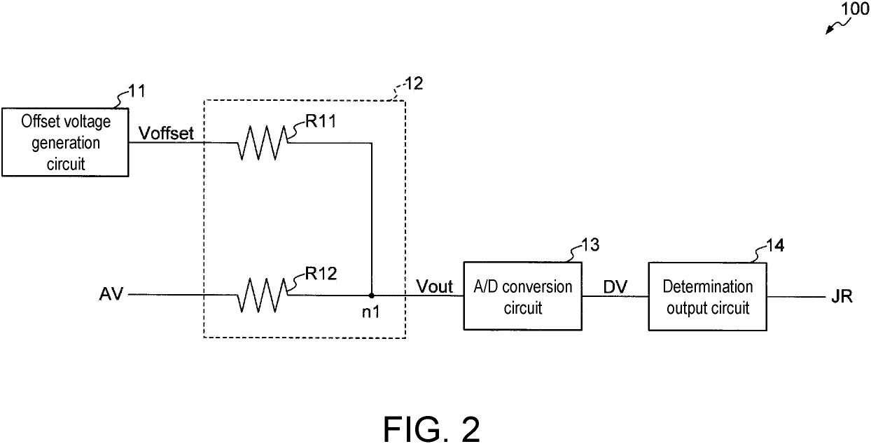

FIG. 2 is a block diagram of the semiconductor device 100 illustrating an example of a configuration of the analog addition circuit 12. The analog addition circuit 12 is constituted by a resistor R11 and a resistor R12.

One end of the resistor R11 is connected to an output terminal of the offset voltage generation circuit 11. The other end of the resistor R11 is connected to a node n1 and is connected to an input terminal of the A/D conversion circuit 13 via the node n1.

The input voltage AV is supplied to one end of the resistor R12. The other end of the resistor R12 is connected to the node n1 and is connected to the input terminal of the A/D conversion circuit 13 via the node n1.

In the analog addition circuit 12 having such a configuration, the output voltage Vout is expressed by the following Formula (1).

$${V}_{o u t} = \frac{{R}_{11} A V + {R}_{12} {V}_{o f f s e t}}{{R}_{11} + {R}_{12}} \qquad \text{(1)}$$

Here, assuming that the resistors R11 and R12 have the same resistance value, that is, the resistor R11 = the resistor R12, the output voltage Vout of the analog addition circuit 12 is expressed by the following Formula (2).

$${V}_{o u t} = \frac{1}{2} \left(A V + {V}_{o f f s e t}\right) \qquad \text{(2)}$$

That is, in a case where the analog addition circuit 12 in FIG. 2 is configured using only resistors having the same resistance value, a voltage obtained by simply adding the input voltage AV and the offset voltage Voffset and dividing this voltage by “2” is an output voltage Vout.

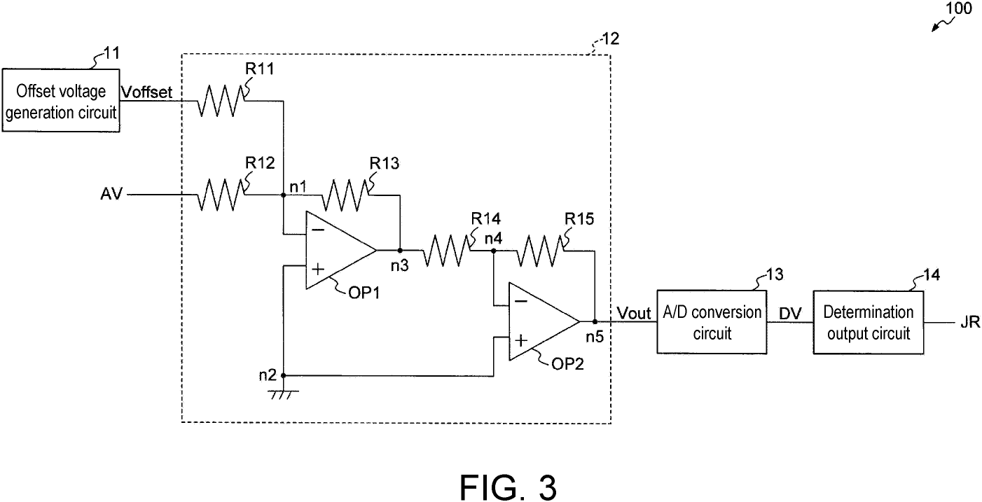

FIG. 3 is a block diagram of the semiconductor device 100 illustrating another example of a configuration of the analog addition circuit 12. The analog addition circuit 12 is constituted by resistors R11, R12, R13, R14, and R15, and operational amplifiers OP1 and OP2.

One end of the resistor R11 is connected to an output terminal of the offset voltage generation circuit 11, and the other end thereof is connected to the node n1. The other end of the resistor R12 is connected to the node n1, and the input voltage AV is supplied to one end thereof.

The operational amplifier OP1 is a non-inverting amplifier circuit that amplifies and outputs an input signal. An inverting input terminal of the operational amplifier OP1 is connected to the node n1 and is connected to the other ends of the resistors R11 and R12 via the node n1. A non-inverting input terminal of the operational amplifier OP1 is connected to a node n2 and is grounded through the node n2. An output terminal of the operational amplifier OP1 is connected to a node n3.

One end of the resistor R13 is connected to the node n1, and is connected to the other ends of the resistors R11 and R12 and the inverting input terminal of the operational amplifier OP1 via the node n1. The other end of the resistor R13 is connected to the node n3 and is connected to the output terminal of the operational amplifier OP1 via the node n3.

One end of the resistor R14 is connected to the node n3, and the resistor R14 is connected to the other end of the resistor R13 and the output terminal of the operational amplifier OP1 via the node n3. The other end of the resistor R14 is connected to a node n4.

The operational amplifier OP2 is a non-inverting amplifier circuit that amplifies and outputs an input signal. An inverting input terminal of the operational amplifier OP2 is connected to the node n4 and is connected to the other end of the resistor R14 via the node n4. A non-inverting input terminal of the operational amplifier OP2 is connected to the node n2 and is grounded via the node n2. The output terminal of the operational amplifier OP2 is connected to a node n5.

One end of the resistor R15 is connected to the node n4, and is connected to the other end of the resistor R14 and the inverting input terminal of the operational amplifier OP2 via a node n14. The other end of the resistor R15 is connected to the node n5 and is connected to the output terminal of the operational amplifier OP2 via the node n5.

In the analog addition circuit 12 having such a configuration, the output voltage Vout is expressed by the following Formula (3).

$${V}_{o u t} = \frac{{R}_{15}}{{R}_{14}} \left(\frac{{R}_{13}}{{R}_{11}} A V + \frac{{R}_{13}}{{R}_{12}} {V}_{o f f s e t}\right) \qquad \text{(3)}$$

Here, assuming that all resistance elements have the same resistance value, that is, the resistors R11 = R12 = R13 = R14 = R15, the output voltage Vout of the analog addition circuit 12 is expressed by the following Formula (4).

$${V}_{o u t} = A V + {V}_{o f f s e t} \qquad \text{(4)}$$

That is, in a case where the analog addition circuit 12 in FIG. 3 is configured using only resistors having the same resistance value, the output voltage Vout is a voltage obtained by simply adding the input voltage AV and the offset voltage Voffset.

The A/D conversion circuit 13 is an analog-digital conversion circuit that performs A/D conversion of a voltage input to the input terminal thereof and outputs the converted voltage. In the present example, the output voltage Vout of the analog addition circuit 12 is supplied to the input terminal of the A/D conversion circuit 13. The A/D conversion circuit 13 performs A/D conversion on the output voltage Vout and outputs the conversion result as a digital voltage DV. That is, the digital voltage DV is a digital voltage signal obtained by performing A/D conversion on the output voltage Vout.

The determination output circuit 14 determines whether a failure such as a ground short-circuit or disconnection has occurred inside the A/D conversion circuit 13, based on the digital voltage DV which is the result of A/D conversion performed by the A/D conversion circuit 13, and outputs a determination signal JR indicating a determination result. For example, in a case where the digital voltage DV is set to “0 V”, the determination output circuit 14 determines that a failure such as a ground short-circuit or disconnection has occurred inside the A/D conversion circuit 13. The determination output circuit 14 is constituted by, for example, a hardware circuit that compares the digital voltage DV with a predetermined value.

In the semiconductor device 100 of the present example, the analog addition circuit 12 performs addition processing on the input voltage AV using the offset voltage Voffset, and the A/D conversion circuit 13 performs A/D conversion on the addition result, thereby generating a digital voltage DV. For this reason, assuming that a failure such as a ground short-circuit does not occur in the A/D conversion circuit 13, the digital voltage DV is higher than 0 V. Thus, in a case where the digital voltage DV is 0 V, it is possible to determine that a failure has occurred in the A/D conversion circuit 13.

The offset voltage Voffset is a voltage having a known voltage value generated using a power supply voltage or the like. For this reason, it is possible to obtain a voltage obtained by performing A/D conversion of the input voltage AV (that is, a digital voltage in a case where analog addition is not performed) based on the known voltage value and the digital voltage DV. Thus, according to the semiconductor device 100 of the present example, it is possible to detect a failure such as a ground short-circuit or disconnection in the A/D conversion circuit 13 by performing A/D conversion and using the result for a normal operation of the device (for example, determination of a collision based on a result of an analog output sensor in an in-vehicle system).

### Example 2

Next, Example 2 of the disclosure will be described.

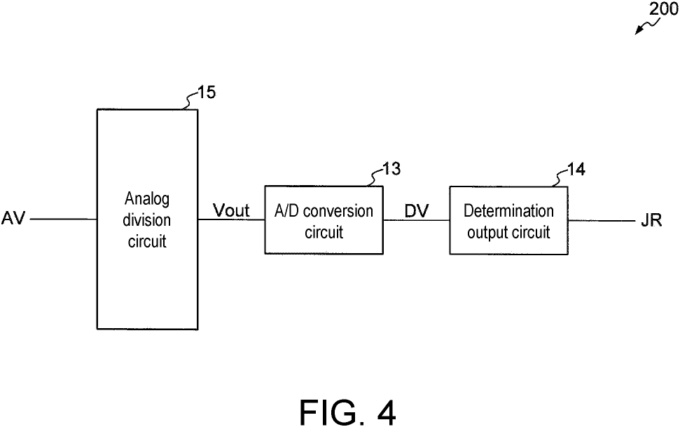

FIG. 4 is a block diagram illustrating a configuration of a semiconductor device 200 according to Example 2 of the disclosure. The semiconductor device 200 is configured as a failure detection circuit that detects a power short-circuit failure inside an A/D conversion circuit 13.

The semiconductor device 200 includes an analog division circuit 15, the A/D conversion circuit 13, and a determination output circuit 14.

The analog division circuit 15 is a circuit that receives the supply of an input voltage AV and performs division processing on the input voltage AV. The analog division circuit 15 outputs the division result as an output voltage Vout. That is, in the present example, the output voltage Vout is a second analog voltage signal obtained by dividing the input voltage AV, which is a first analog voltage signal, by a predetermined value. The analog division circuit 15 has an input end for receiving the input voltage AV.

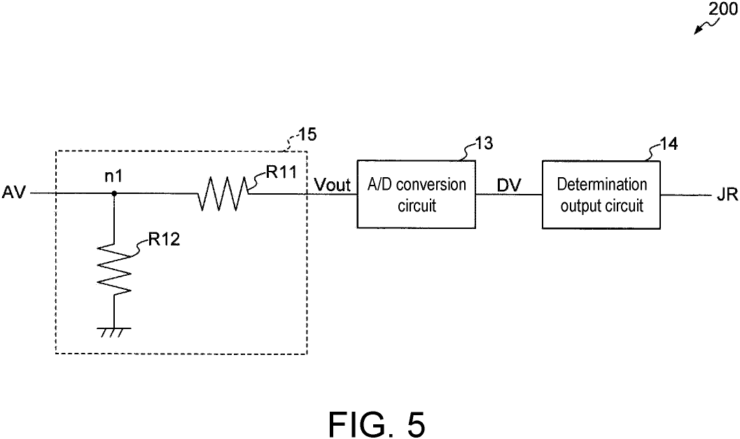

FIG. 5 is a block diagram of the semiconductor device 200 illustrating a configuration example of the analog division circuit 15. The analog division circuit 15 is constituted by a resistor R11 and a resistor R12.

One end of the resistor R11 is connected to a node n1, and the other end thereof is connected to an input terminal of the A/D conversion circuit 13. One end of the resistor R12 is grounded, and the other end thereof is connected to the node n1. The input voltage AV is supplied to the node n1.

In the analog division circuit 15 having such a configuration, the output voltage Vout is represented by the following Formula (5).

$${V}_{o u t} = \frac{{R}_{11} A V}{{R}_{11} + {R}_{12}} \qquad \text{(5)}$$

Here, assuming that the resistors R11 and R12 have the same resistance value, that is, the resistor R11 = the resistor R12, the output voltage Vout of the analog division circuit 15 is expressed by the following Formula (6).

$${V}_{o u t} = \frac{A V}{2} \qquad \text{(6)}$$

That is, in a case where the analog division circuit 15 in FIG. 5 is configured using only resistors having the same resistance value, a voltage obtained by dividing the input voltage AV by “2” is the output voltage Vout.

The A/D conversion circuit 13 receives the supply of the output voltage Vout of the analog division circuit 15 at its input terminal, and performs analog-digital (A/D) conversion on the output voltage Vout. The A/D conversion circuit 13 outputs a conversion result as a digital voltage DV.

The determination output circuit 14 determines whether a “power short-circuit” failure has occurred inside the A/D conversion circuit 13 based on the digital voltage DV that is the result of A/D conversion performed by the A/D conversion circuit 13, and outputs a determination signal JR indicating a determination result. For example, in a case where the determination output circuit 14 determines that the digital voltage DV has reached a reference voltage RV, the determination output circuit 14 determines that a power short-circuit has occurred inside the A/D conversion circuit 13. Here, the reference voltage RV is a maximum value of an input voltage assumed when a power short-circuit occurs in the A/D conversion circuit 13, and is calculated based on, for example, a power supply voltage (not illustrated) supplied to the semiconductor device 200 as an operating voltage.

In the semiconductor device 200 of the present example, the analog division circuit 15 performs division processing on the input voltage AV, and the A/D conversion circuit 13 performs A/D conversion on a division result, thereby generating a digital voltage DV. For this reason, assuming that a power short-circuit failure has not occurred in the A/D conversion circuit 13, the digital voltage DV is a voltage smaller than a voltage obtained by performing A/D conversion on a maximum voltage (analog voltage) assumed to be an input voltage of the A/D conversion circuit 13. Thus, in a case where the digital voltage DV has reached the reference voltage RV, it is possible to determine that a power short-circuit failure has occurred in the A/D conversion circuit 13.

The predetermined value used for division by the analog division circuit 15 is a known value determined based on the resistance values of the resistors R11 and R12, as described above. For this reason, it is possible to obtain a digital voltage obtained by performing A/D conversion of the input voltage AV (that is, a digital voltage in a case where division is not performed) based on the predetermined value and the digital voltage DV. Thus, according to the semiconductor device 200 of the present example, it is possible to detect a power short-circuit failure in the A/D conversion circuit 13 by performing A/D conversion and using the result for a normal operation of the device (for example, determination of a collision based on a result of an analog output sensor in an in-vehicle system).

### Example 3

Next, Example 3 of the disclosure will be described.

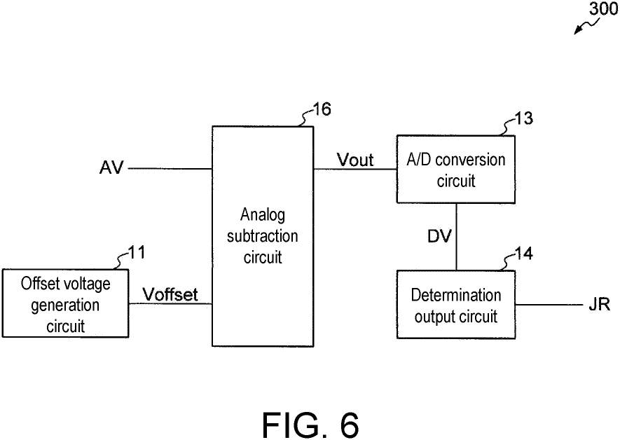

FIG. 6 is a block diagram illustrating a configuration of a semiconductor device 300 according to Example 3 of the disclosure. Similarly to the semiconductor device 200 in Example 2, the semiconductor device 300 is configured as a failure detection circuit that detects a power short-circuit failure inside the A/D conversion circuit 13.

The semiconductor device 300 includes an offset voltage generation circuit 11, an analog subtraction circuit 16, an A/D conversion circuit 13, and a determination output circuit 14.

The offset voltage generation circuit 11 is a circuit that generates an offset voltage Voffset, which is an analog voltage used for subtraction by the analog subtraction circuit 16. The offset voltage generation circuit 11 generates the offset voltage Voffset based on, for example, a power supply voltage (not illustrated) supplied as an operating voltage from the outside of the semiconductor device 300.

The analog subtraction circuit 16 is a circuit that performs subtraction processing on an input voltage AV using the offset voltage Voffset. The subtraction processing in the present example includes not only simple subtraction of simply subtracting the offset voltage Voffset from the input voltage AV, but also subtraction performed by performing predetermined weighting thereon. The analog subtraction circuit 16 includes a first input terminal for receiving an input of the offset voltage Voffset and a second input terminal for receiving an input of the input voltage AV.

The analog subtraction circuit 16 outputs a subtraction result as the output voltage Vout. That is, in the present example, the output voltage Vout is a second analog voltage signal obtained by subtracting the offset voltage Voffset from the input voltage AV which is a first analog voltage signal.

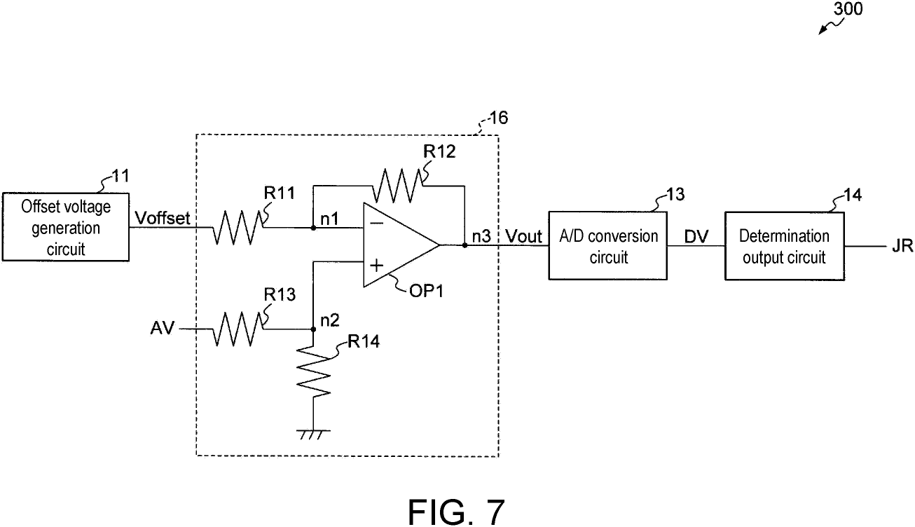

FIG. 7 is a block diagram of the semiconductor device 300 illustrating a configuration example of the analog subtraction circuit 16. The analog subtraction circuit 16 is constituted by resistors R11, R12, R13, and R14 and an operational amplifier OP1.

One end of the resistor R11 is connected to an output terminal of the offset voltage generation circuit 11, and the other end thereof is connected to a node n1.

The operational amplifier OP1 is a non-inverting amplifier circuit that amplifies and outputs an input signal. An inverting input terminal of the operational amplifier OP1 is connected to the node n1 and is connected to the other end of the resistor R11 via the node n1. A non-inverting input terminal of the operational amplifier OP1 is connected to a node n2.

One end of the resistor R12 is connected to the node n1, and is connected to the other end of the resistor R11 and the inverting input terminal of the operational amplifier OP1 via the node n1. The other end of the resistor R12 is connected to a node n3 and is connected to the output terminal of the operational amplifier OP1 via the node n3.

The input voltage AV is supplied to one end of the resistor R13. The other end of the resistor R13 is connected to the node n2 and is connected to the non-inverting input terminal of the operational amplifier OP1 via the node n2.

One end of the resistor R14 is grounded. The other end of the resistor R14 is connected to the node n2, and is connected to the other end of the resistor R13 and the non-inverting input terminal of the operational amplifier OP1 via the node n2.

In the analog subtraction circuit 16 having such a configuration, the output voltage Vout is expressed by the following Formula (7).

$${V}_{o u t} = \left(\frac{{R}_{11} + {R}_{12}}{{R}_{11}}\right) \left(\frac{{R}_{14} A V}{{R}_{13} + {R}_{14}} - \frac{{R}_{12} {V}_{o f f s e t}}{{R}_{11} + {R}_{12}}\right) \qquad \text{(7)}$$

Here, assuming that all resistance elements have the same resistance value, that is, the resistors R11 = R12 = R13 = R14, the output voltage Vout of the analog subtraction circuit 16 is expressed by the following Formula (8).

$${V}_{o u t} = A V - {V}_{o f f s e t} \qquad \text{(8)}$$

That is, in a case where the analog subtraction circuit 16 in FIG. 7 is configured using only resistors having the same resistance value, a voltage obtained by simply subtracting the offset voltage Voffset from the input voltage AV is an output voltage Vout.

The A/D conversion circuit 13 receives the supply of the output voltage Vout of the analog subtraction circuit 16 at its input terminal, and performs analog-digital (A/D) conversion on the output voltage Vout. The A/D conversion circuit 13 outputs a conversion result as a digital voltage DV.

The determination output circuit 14 determines whether a “power short-circuit” failure has occurred inside the A/D conversion circuit 13 based on the digital voltage DV that is the result of A/D conversion performed by the A/D conversion circuit 13, and outputs a determination signal JR indicating a determination result. For example, in a case where the determination output circuit 14 determines that the digital voltage DV has reached a reference voltage RV, the determination output circuit 14 determines that a power short-circuit has occurred inside the A/D conversion circuit 13.

In the semiconductor device 300 of the present example, the analog subtraction circuit 16 performs subtraction processing of the input voltage AV using the offset voltage Voffset, and the A/D conversion circuit 13 performs A/D conversion on a subtraction result, thereby generating a digital voltage DV. For this reason, assuming that a power short-circuit failure has not occurred in the A/D conversion circuit 13, the digital voltage DV is a voltage smaller than a voltage obtained by performing A/D conversion on a maximum voltage (analog voltage) assumed to be an input voltage of the A/D conversion circuit 13. Thus, in a case where the digital voltage DV has reached the reference voltage RV, it is possible to determine that a power short-circuit failure has occurred in the A/D conversion circuit 13.

The offset voltage Voffset is a voltage having a known voltage value generated using a power supply voltage or the like. For this reason, it is possible to obtain a voltage, which is obtained by performing A/D conversion of the input voltage AV (that is, a digital voltage in a case where analog subtraction is not performed) based on the known voltage value and the digital voltage DV. Thus, according to the semiconductor device 300 of the present example, it is possible to detect a power short-circuit failure in the A/D conversion circuit 13 by performing A/D conversion and using the result for a normal operation of the device (for example, determination of a collision based on a result of an analog output sensor in an in-vehicle system).

The disclosure is not limited to the above-described embodiment. For example, in the above-described example, a case where the determination output circuit 14 is constituted by a hardware circuit has been described as an example. However, the disclosure is not limited thereto, and the determination output circuit 14 may be constituted by software.

Further, the circuit configurations of the analog addition circuit 12, the analog division circuit 15, and the analog subtraction circuit 16 are not limited to those shown in the above-described examples.

In the above-described Example 1, a case where it is determined whether a failure such as a ground short-circuit or disconnection has occurred, based on whether the digital voltage DV is “0 V” has been described. However, a reference voltage value for determining whether a failure has occurred is not necessarily limited to “0 V”, and a predetermined voltage level (signal level) equal to or less than the offset voltage Voffset may be used as the reference for determination. Similarly, the reference voltage RV in Examples 2 and 3 is not limited to the voltages described in the above-described examples.

The configurations of the above-described examples can be used in combination as appropriate. For example, a configuration may also be adopted in which Example 1 and Example 2 are combined to enable both the detection of a ground short-circuit or disconnection and the detection of a power short-circuit.

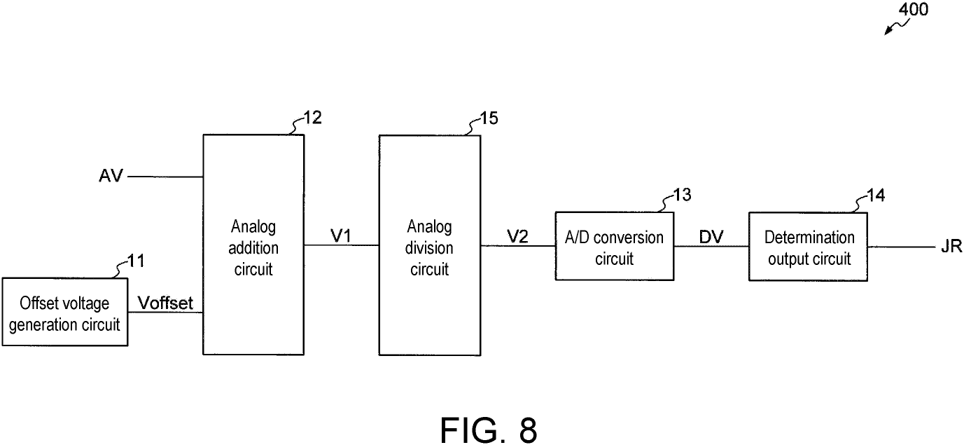

FIG. 8 is a block diagram illustrating a configuration of a semiconductor device 400 according to a modification example in which the configuration of Example 1 and the configuration of Example 2 are combined with each other.

The semiconductor device 400 includes an offset voltage generation circuit 11, an analog addition circuit 12, an analog division circuit 15, an A/D conversion circuit 13, and a determination output circuit 14.

The analog addition circuit 12 performs addition processing on an input voltage AV using an offset voltage Voffset, and outputs an addition result as a first output voltage V1.

The analog division circuit 15 performs division processing on the first output voltage V1 and outputs a division result as a second output voltage V2.

The A/D conversion circuit 13 performs A/D conversion on the second output voltage V2 and outputs a conversion result as a digital voltage DV.

The determination output circuit 14 determines whether a failure has occurred in the A/D conversion circuit 13 based on the digital voltage DV that is a result of the A/D conversion performed by the A/D conversion circuit 13. Specifically, in a case where the digital voltage DV is “0 V”, the determination output circuit 14 determines that a failure such as a ground short-circuit or disconnection has occurred inside the A/D conversion circuit 13. In a case where the digital voltage DV reaches a reference voltage RV, the determination output circuit 14 determines that a power short-circuit failure has occurred inside the A/D conversion circuit 13.

In the semiconductor device 400 having the configuration illustrated in FIG. 8, the offset voltage Voffset is added to the input voltage AV, and the analog division circuit 15 performs division processing. For this reason, assuming that a failure has not occurred in the A/D conversion circuit 13, the digital voltage DV is higher than 0 V and lower than the reference voltage RV. Thus, it is possible to detect both a failure due to a ground short-circuit or disconnection and a failure due to a power short-circuit.

What is claimed is:

1. A semiconductor device comprising:
an addition circuit that receives an input of a first analog voltage signal and adds an offset voltage to the first analog voltage signal to generate a second analog voltage signal;
an AD conversion circuit that performs AD conversion of the second analog voltage signal to generate a digital voltage signal; and
a determination circuit that determines whether a failure has occurred in the AD conversion circuit based on the digital voltage signal.

2. The semiconductor device according to claim 1, wherein the determination circuit determines whether a failure of a ground short-circuit or disconnection has occurred in the AD conversion circuit, based on whether a signal level of the digital voltage signal is a predetermined signal level equal to or lower than the offset voltage.

3. The semiconductor device according to claim 1, wherein the addition circuit includes
a first input terminal for receiving an input of the offset voltage,
a second input terminal for receiving an input of the first analog voltage signal,
a first resistance element inserted between a node connected to an input part of the AD conversion circuit and the first input terminal, and
a second resistance element inserted between the node and the second input terminal.

4. The semiconductor device according to claim 2, wherein the addition circuit includes
a first input terminal for receiving an input of the offset voltage,
a second input terminal for receiving an input of the first analog voltage signal,
a first resistance element inserted between a node connected to an input part of the AD conversion circuit and the first input terminal, and
a second resistance element inserted between the node and the second input terminal.

5. The semiconductor device according to claim 1, wherein the addition circuit includes
a first input terminal for receiving an input of the offset voltage,
a second input terminal for receiving an input of the first analog voltage signal,
a first resistance element having one end connected to the first input terminal,
a second resistance element having one end connected to the second input terminal,
a third resistance element having one end connected to a first node connecting the other end of the first resistance element and the other end of the second resistance element,
a first operational amplifier having a non-inverting input terminal grounded, an inverting input terminal connected to the first node, and an output terminal connected to the other end of the third resistance element,
a fourth resistance element having one end connected to a second node connecting the output terminal of the first operational amplifier and the other end of the third resistance element,
a fifth resistance element having one end connected to the other end of the fourth resistance element, and
a second operational amplifier having a non-inverting input terminal grounded, an inverting input terminal connected to a third node connecting the other end of the fourth resistance element and one end of the fifth resistance element, and an output terminal connected to the other end of the fifth resistance element.

6. The semiconductor device according to claim 2, wherein the addition circuit includes
a first input terminal for receiving an input of the offset voltage,
a second input terminal for receiving an input of the first analog voltage signal,
a first resistance element having one end connected to the first input terminal,
a second resistance element having one end connected to the second input terminal,
a third resistance element having one end connected to a first node connecting the other end of the first resistance element and the other end of the second resistance element,
a first operational amplifier having a non-inverting input terminal grounded, an inverting input terminal connected to the first node, and an output terminal connected to the other end of the third resistance element,
a fourth resistance element having one end connected to a second node connecting the output terminal of the first operational amplifier and the other end of the third resistance element,
a fifth resistance element having one end connected to the other end of the fourth resistance element, and
a second operational amplifier having a non-inverting input terminal grounded, an inverting input terminal connected to a third node connecting the other end of the fourth resistance element and one end of the fifth resistance element, and an output terminal connected to the other end of the fifth resistance element.

7. A semiconductor device comprising:
a division circuit that receives an input of a first analog voltage signal and divides the first analog voltage signal by a predetermined value to generate a second analog voltage signal;
an AD conversion circuit that performs AD conversion of the second analog voltage signal to generate a digital voltage signal; and
a determination circuit that determines whether a failure has occurred in the AD conversion circuit based on the digital voltage signal.

8. The semiconductor device according to claim 7, wherein the determination circuit determines whether a power short-circuit failure has occurred in the AD conversion circuit based on a signal level of the digital voltage signal.

9. The semiconductor device according to claim 7, wherein the division circuit includes
an input terminal for receiving an input of the first analog voltage signal,
a first resistance element inserted between the input terminal and an input part of the AD conversion circuit, and
a second resistance element having one end grounded and the other end connected to a node connecting the input terminal and one end of the first resistance element.

10. The semiconductor device according to claim 8, wherein the division circuit includes
an input terminal for receiving an input of the first analog voltage signal,
a first resistance element inserted between the input terminal and an input part of the AD conversion circuit, and
a second resistance element having one end grounded and the other end connected to a node connecting the input terminal and one end of the first resistance element.

11. A semiconductor device comprising:
a subtraction circuit that receives an input of a first analog voltage signal and subtracts an offset voltage from the first analog voltage signal to generate a second analog voltage signal;
an AD conversion circuit that performs AD conversion of the second analog voltage signal to generate a digital voltage signal; and
a determination circuit that determines whether a failure has occurred in the AD conversion circuit based on the digital voltage signal.

12. The semiconductor device according to claim 11, wherein the determination circuit determines whether a power short-circuit failure has occurred in the AD conversion circuit based on a signal level of the digital voltage signal.

13. The semiconductor device according to claim 11, wherein the subtraction circuit includes
a first input terminal for receiving an input of the offset voltage,
a second input terminal for receiving an input of the first analog voltage signal,
a first resistance element having one end connected to the first input terminal,
a second resistance element having one end connected to the other end of the first resistance element,
a third resistance element having one end connected to the second input terminal,
a fourth resistance element having one end grounded and the other end connected to the other end of the third resistance element, and
an operational amplifier having an inverting input terminal connected to a first node, which connects the other end of the first resistance element and one end of the second resistance element, a non-inverting input terminal connected to a second node connecting the other end of the third resistance element and the other end of the fourth resistance element, and an output terminal connected to an input part of the AD conversion circuit together with the other end of the second resistance element.

14. The semiconductor device according to claim 12, wherein the subtraction circuit includes
a first input terminal for receiving an input of the offset voltage,
a second input terminal for receiving an input of the first analog voltage signal,
a first resistance element having one end connected to the first input terminal,
a second resistance element having one end connected to the other end of the first resistance element,
a third resistance element having one end connected to the second input terminal,
a fourth resistance element having one end grounded and the other end connected to the other end of the third resistance element, and
an operational amplifier having an inverting input terminal connected to a first node, which connects the other end of the first resistance element and one end of the second resistance element, a non-inverting input terminal connected to a second node connecting the other end of the third resistance element and the other end of the fourth resistance element, and an output terminal connected to an input part of the AD conversion circuit together with the other end of the second resistance element.
